(19) United States
(12) Patent Application Publication
(10) Pub. No.: US 2002/0011201 A1
(43) Pub. Date: Jan. 31, 2002

(54) Controlled source for material processing

(75) Inventors: Zong-Long Liau, Belmont, MA (US); Margaret B. Stern, Sudbury, MA (US)

Correspondence Address: J GRANT HOUSTON, AXSUN TECHNOLOGIES INC, 1 FORTUNE DRIVE, BILLERICA, MA, 01821, US

(73) Assignee: AXSUN Technologies, Inc.

(21) Appl. No.: 09/908,237

(22) Filed: Jul. 18, 2001

Related U.S. Application Data
(60) Provisional application No. 60/220,573, filed on Jul. 25, 2000.

(51) Int. Cl. C30B 28/12; C30B 23/00; C30B 28/14; C30B 25/00

(52) U.S. Cl. 117/84

(57) ABSTRACT

An apparatus and method for creating a supply of group V vapor required for various material processing applications such as crystal growth or the mass transport process, when applied to III-V materials (e.g., GaP) comprises a stable source of group V material (e.g., a GaP wafer), a process tube, and inner tube, a three-zone furnace incorporating a cold trap zone for the group III material, and a “loose” plug for the process tube. The phosphorus vapor is generated by using a source GaP wafer placed at a higher temperature than that of the main process wafer in the mass transport process. When high phosphorous vapor concentration is desired, other solid sources such as InP or red P can be used. To minimize vapor loss to the ambient, both wafers are enclosed in a quartz tube equipped with a quartz plug. However, the source wafer generates not only phosphorus but also gallium vapor. The latter interferes with mass transport and needs to be filtered out. This is conveniently accomplished by employing a larger (longer) process tube and by further placing the source in a smaller inner tube within the main process tube. The source inner tube first directs the vapor to a cooler region, where gallium is selectively condensed out before it reaches the process wafer.

### BACKGROUND OF THE INVENTION

The use of the so-called mass transport (MT) process as a means of reshaping the surface profile of semiconductor materials has been recognized for many years. For example, U.S. Pat. Nos. 4,718,070; 4,935,939; and 5,618,474 concern MT, particularly as applied to III-V materials, GaP in particular.

One step in the MT process requires the creation of an overpressure of the group V material vapor in the region of the process wafer, viz., the wafer on which the re-shaping is intended. In this atmosphere, the surface of the process wafer is continually giving up and re-acquiring matter, with the net effect of redistributing the material laterally along the surface, hence the name mass transport.

Four basic approaches have been used to create the appropriate overpressure conditions for MT. First, the process wafer can be immersed in a flow of gaseous material already rich in the group V material; for GaP processing this material is phosphine gas.

Unfortunately, phosphine is extremely toxic and this process continuously produces a stream of hazardous waste material. The second approach is to use a sealed ampoule inside a two zone furnace. The ampoule contains both the process wafer and a fixed amount of source material. The source material is totally vaporized to create the required overpressure. This approach is safe but suffers from several problems. First, the ampoule is sealed, so each manufacturing run requires quartz sealing and breaking steps. Second, it is difficult to perform a thorough in situ baking prior to the ampoule sealing. The third approach is to use a melt containing the III-V material located in the vicinity of the main wafer. This approach, however, is quite crude, because it not only lacks the precise control of the vapors but also releases much of the vapor to the ambient. The fourth approach is to use a cover wafer that is made of the same material as the main wafer. This suffers from similar problems as those in the melt approach.

### SUMMARY OF THE INVENTION

The invention is directed to the elimination of some or all of the above difficulties and further can create the required overpressure vapor. The invention can also be applied to other material processing operations that require a controlled source of group V vapor.

This invention is an apparatus and method for creating a supply of group V vapor required for various materials processing applications such as crystal growth or the mass transport process, when applied to III-V materials (e.g., GaP). The apparatus comprises a stable source of group V material (e.g., a GaP wafer), a process tube, and inner tube, a three-zone furnace incorporating a cold trap zone for the group III material, and a “loose” plug for the process tube.

In more detail, the phosphorus vapor is generated by using, for example, a GaP source wafer that is placed at a higher temperature than that of the process wafer in the mass transport process. When high phosphorous vapor concentration is desired, other solid sources such as InP or red P can be used. In particular, InP provides a stable high phosphorus vapor at a much lower temperature than that of GaP. To minimize vapor loss to the ambient, both wafers are enclosed in a quartz tube equipped with a quartz plug.

The source wafer, however, generates not only phosphorus but also gallium vapor (or indium vapor when InP is used). The latter can interfere with mass transport and needs to be filtered out. This is conveniently accomplished by employing a larger (longer) process tube and by further placing the source in a smaller inner tube within the main process tube. The source inner tube first directs the vapor to a cooler region, where gallium (or indium) is selectively condensed out, preventing it from reaching the process wafer.

The entire process tube is placed in an open furnace tube with argon flow, which is inert and safe. Prior to the argon purge, the system can be evacuated and the contents of the process tube baked in situ.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIG. 1 is schematic block diagram of a mass transport processing system according to the present invention; and

FIG. 2 is a schematic cross-sectional view of a mass transport furnace according to the present invention.

### DETAILED DESCRIPTION OF THE PREFERRED EMBODIMENTS

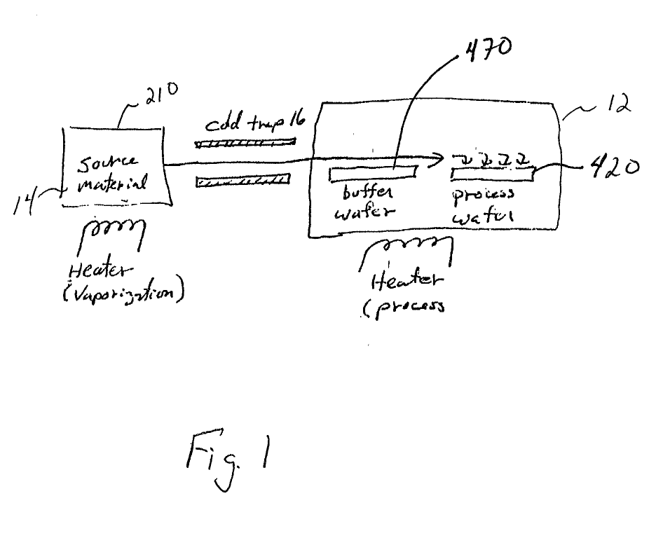

Referring to FIG. 1, the stable source 210 of group V material is shown at the left hand (starting) end of the diagram. This material is held at a temperature that is appropriate for creating group V vapor at the desired vapor pressure. Since the group V source material is often part of a III-V compound, the vapor is directed past a cooler region of the apparatus, which forms a cold trap 16, where any group III material or other contaminants condense out.

The remaining group V vapor continues into the process region 12, passing over an expendable sample of target material on its way to the process wafer 420.

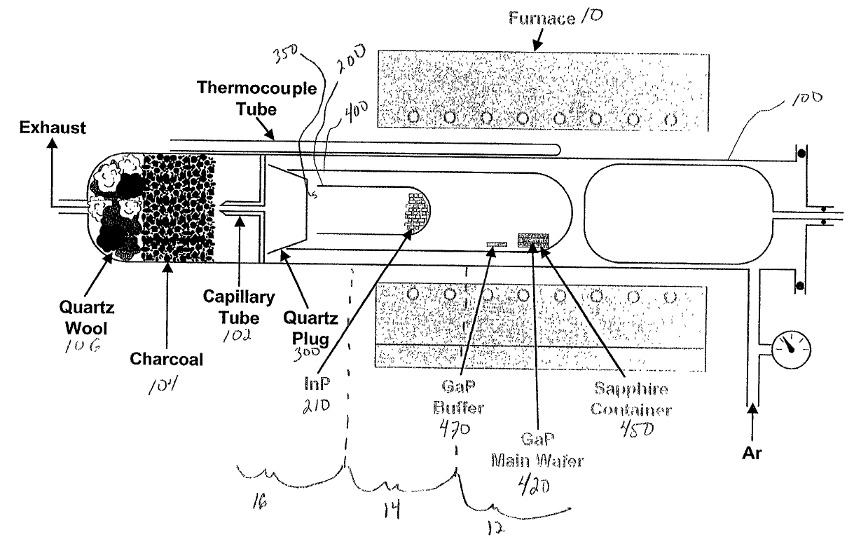

Referring to FIG. 2, an apparatus that is constructed according to the principles of the invention comprises a three temperature-zone furnace 10 surrounding a “loosely” plugged, quartz process tube 400, an open-ended inner tube 200 containing a stable, expendable source of group V material, and an expendable buffering wafer 470 at the edge of the process-wafer region 12.

Although one embodiment has the source material in the inner tube 200, it is also possible to use the interior of the inner tube as the process zone and to place the source material in the end of the process tube.

A furnace tube 100 is sized and dimensioned based on the capacity of the furnace 10. Typically, the furnace will have a cylindrical chamber with the three temperature zones (12, 14, 16) along the cylinder axis. The vaporization or hot zone 14, Tv, is in the center, the cold trap zone 16, Tc, is shown near the mouth of the furnace tube, and the process temperature zone 12, Tp, is shown at the far end of the furnace tube 100.

This arrangement of zones is the current configuration with the key aspect being that the cold trap zone isolates the vaporization zone 14 from the process zone 12.

In the preferred embodiment, when used for the MT process, the process wafer 420 is placed deep into the process tube 400 so that it is located in the process zone 12. A containment wafer 450 typically made from sapphire, is fixtured at a distance of about 1-50 micrometers from the process wafer. A buffer wafer 470, which is preferably made from the same material as the process wafer 420, is located at the boundary between the process zone 12 and the hot zone 14.

The inner tube 200 is a single ended tube (similar to a test tube), typically quartz, that contains, close to its closed end, a donor source 210 of group V material appropriate for the process. For the example of most interest, where GaP is being processed, a convenient donor source is another wafer of GaP or InP. The inner tube 200 is placed in the furnace tube 400 such that the donor source is in the middle of the Tv zone 14 and the open end is at least at the edge of the cold-trap zone 16.

Finally, the process tube 400 is sealed by a “loose” seal 300 that reduces diffusion losses during processing but allows in situ bake-out of the loaded system. Typically, the seal may be made from quartz. The quartz plug and the mouth of the process tube can be precisely ground for a consistent effective seal that is not entirely vacuum tight. The seal effectiveness can be tested by measuring the escape (evaporative) rate of methanol at room temperature.

In operation the entire, sealed process tube 400 is placed in the open furnace tube 100. The furnace tube 100 is evacuated so the contents of the process tube are baked-out in situ. After the bake-out has eliminated possible contamination, the furnace tube 100 is purged with an argon flow.

10 Another proposed technique utilizes the furnace itself for pumping and purging with argon gas, without the need for any additional pump. The furnace 10 is first heated to a moderate temperature of 300-900° C. It is then slid or positioned to heat up the process tube 400 in order to drive out the gas inside by thermal expansion. The furnace 10 is then slid out so that the process tube 400 cools, drawing in the clean Ar gas. This process can be repeated several times to achieve a thorough pumping and purging.

Yet another technique for self-pumping involves heating the source wafer crystal and using the additional Group V vapor (osmic) pressure to pump the tube.

The furnace 10 is brought to temperature at which the donor or source wafer 210 gives-off its group V material. Since the most convenient source material is a stable III-V compound, some group III material is also released from the source. Both the species diffuse out of the inner tube 200. Because of the serpentine diffusion path 350, the molecules must pass through the cold-trap zone 16. In this zone the group III material, which has a lower vapor pressure, selectively plates out and is thus removed from the vapor reaching the process zone 12.

The group V vapor migrates to the process zone where it becomes involved with the process wafer 420. As shown in the figure, when the process to which this invention is applied is the mass transport process, it is desirable to add a buffer wafer 470 before the process wafer 420. For other processes, this wafer may not be useful.

The preferred temperatures for the furnace zones are substantially dependent on the specific materials used for the source and process wafers, but generally, we have found Tp to be about 1050-1150° C., Tv to be 950-1100° C., and Tc to be in the range of 400 to 600° C. when InP is the source material and GaP is the process material.

The phosphorus vapor that leaks out of the quartz plug 300 tends to be pushed by the gas flow and eventually forms phosphorus deposits in the rear section of the furnace tube 100.

This phosphorus can then trap oxygen and moisture contaminants when the system is opened for loading and unloading.

An effective throttling section is implemented in the furnace tube 100 to restrict any back diffusion from the rear section to the process tube 400. The effective throttling can be provided by: 1) a narrowing of the flow by a capillary tube section 102 (typically 0.5 millimeters in diameter and 15 centimeter length); or 2) stuffing the furnace tube with quartz wool in place of the capillary tube. The phosphorus in the rear section is further absorbed by charcoal 104 and stopped by quartz-wool stuffing 106 at the rear end, so that the phosphorus is fully contained and the rest of the system is kept clean.

Another example technique used coiled quartz tubing to increase the effective length or implementing a rear baffle tube with well-controlled dimensions to narrow down the cross-sectional area.

It should be noted that this method of generating a clean, safe, and controlled vapor source is applicable to other compound materials, including, but not limited to III-V and II-VI material systems.

While this invention has been particularly shown and described with references to preferred embodiments thereof, it will be understood by those skilled in the art that various changes in form and details may be made therein without departing from the scope of the invention encompassed by the appended claims.

What is claimed is:

1. A semiconductor material processing system, comprising:
a furnace;
a vapor source for producing a first vaporized material and a second vaporized material when heated by the furnace;
a process wafer, heated by the furnace, for receiving the first vaporized material; and
a cold trap in a vapor path between the vapor source and the process wafer for trapping the second vaporized material.

2. A processing system as claimed in claim 1, wherein the vapor source comprises a group III-V material.

3. A processing system as claimed in claim 1, wherein the vapor source comprises a group II-VI material.

4. A processing system as claimed in claim 1, wherein vapor source is a stable compound.

5. A processing system as claimed in claim 1, further comprising a throttling section that restricts back diffusion in the furnace.

6. A method for producing an overpressure of a desired material at a process wafer in a mass transport process, the method comprising:
heating a source material to produce a vaporized desired material and a vaporized undesired material;
cooling the vaporized desired material and a vaporized undesired material to condense the undesired material; and
flowing the vaporized desired material to a process wafer to facilitate a mass transport process thereon.

7. A method as claimed in claim 6, wherein the step of heating the source material comprises heating a group III-V material.

8. A method as claimed in claim 6, wherein the step of heating the source material comprises heating a group II-VI material.

9. A method as claimed in claim 6, further comprising purging a process region by heating the process region.
